(19) United States
(12) Patent Application Publication
(10) Pub. No.: US 2023/0367079 A1
(43) Pub. Date: Nov. 16, 2023

(54) LIGHT SOURCE UNIFORMITY ADJUSTING DEVICE, OPTICAL DEVICE INCLUDING THE SAME, AND LIGHT SOURCE UNIFORMITY ADJUSTING METHOD

(71) Applicant: SAMSUNG ELECTRONICS CO., LTD., Suwon-si (KR)

(72) Inventors: Sung-Il Choi, Suwon-si (KR); Hyong Joon Kim, Paju-si (KR); Jong Koo Im, Asan-si (KR); Kyung Beom Kim, Hwaseong-si (KR); Sung Yoon Ryu, Hwaseong-si (KR); Mi Ra Park, Suwon-si (KR); Jeong Han Yi, Suwon-si (KR); Jeung Hee Lee, Suwon-si (KR)

(73) Assignees: SAMSUNG ELECTRONICS CO., LTD., Suwon-si (KR); SEMES CO., LTD., Cheonan-si (KR)

(21) Appl. No.: 18/096,255

(22) Filed: Jan. 12, 2023

(30) Foreign Application Priority Data
May 12, 2022 (KR) 10-2022-0058452

(51) Int. Cl. G02B 6/36

(52) U.S. Cl. CPC G02B 6/3652; G01N 21/9501

(57) ABSTRACT

A light source uniformity adjusting device is provided, which easily and exactly performs a coiling task of an optical fiber. The light source uniformity adjusting device includes a base plate including a plurality of holes therein; a first fixing portion on one side of the base plate, fixing a first portion of an optical fiber; a second fixing portion disposed on another side of the base plate, fixing a second portion of the optical fiber; and a post portion inserted into at least one hole from among the plurality of holes, the post portion routing the optical fiber on the base plate such that the optical fiber has at least one curved shape between the first portion and the second portion.

### CROSS-REFERENCE TO RELATED APPLICATION

This application claims priority from Korean Patent Application No. 10-2022-0058452 filed on May 12, 2022, in the Korean Intellectual Property Office, and all the benefits accruing therefrom under 35 U.S.C. 119, the contents of which in its entirety are herein incorporated by reference.

### BACKGROUND

### 1 Technical Field

Embodiments of the present disclosure relate to a light source uniformity adjusting device, an optical device including the same, and a light source uniformity adjusting method.

### 1 Description of the Related Art

As a semiconductor manufacturing process is highly integrated, a three-dimensional profile measurement technology for semiconductor fine patterns and complex structures has been developed. Recently, in case of memory and logic products, wafers have been manufactured using a fine process technology having a line width of 20 nm or less, and a high-speed fine pattern process monitoring technology has been required to improve wafer yield and quality. Process defect inspection and profile measurement technologies can be largely categorized into an optical method and a method using an electron beam, and the optical method is preferred in terms of inspection speed. However, as patterns are recently manufactured with line widths of optical resolution or less, conventional optical methods have limitations in measuring three-dimensional (3D) profiles. To solve this problem, an optical critical dimension (OCD) technique, which is a profile extraction technology through electromagnetic analysis of light scattered from fine patterns, has been developed and used for 3D profile analysis.

Meanwhile, light used in the optical method may be transmitted through an optical fiber. The optical fiber can be categorized into a multi-mode optical fiber having an inner core of a relatively large diameter and a single mode optical fiber having an inner core of a relatively small diameter. When the multi-mode optical fiber is used, since light of various modes passes within a valid area, uniformity of light may not be constant.

In order to obtain uniform light, it may be required to route optical fibers inside the multi-mode optical fiber, and this is called a coiling task. That is, uniform light may be induced by changing a shape of the multi-mode optical fiber to an O type, a U type, or the like. However, quality of the coiling task varies depending on a skill-level of a worker, and a variation in the task time is also large.

### SUMMARY

According to embodiments of the present disclosure, a light source uniformity adjusting device is provided for easily and exactly performing a coiling task of an optical fiber.

According to embodiments of the present disclosure, a light source device is provided for easily and exactly performing a coiling task of an optical fiber.

According to embodiments of the present disclosure, a light source uniformity adjusting method is provided for easily and exactly performing a coiling task of an optical fiber.

According to embodiments of the present disclosure, a light source uniformity adjusting device is provided. The light source uniformity adjusting device includes: a base plate including a plurality of holes therein; a first fixing portion on one side of the base plate, fixing a first portion of an optical fiber; a second fixing portion disposed on another side of the base plate, fixing a second portion of the optical fiber; and a post portion inserted into at least one hole from among the plurality of holes, the post portion routing the optical fiber on the base plate such that the optical fiber has at least one curved shape between the first portion and the second portion.

According to embodiments of the present disclosure, an optical device is provided. The optical device includes: a light source configured to provide incident light to a substrate; and a detector configured to detect reflective light that is generated by reflecting the incident light from the substrate, and the detector further configured to generate a spectral image. The light source includes a light generator configured to generate the incident light, an optical fiber configured to transfer the incident light, and an adjusting device configured to coil the optical fiber. The adjusting device includes: a base plate including a plurality of holes therein, a first fixing portion on one side of the base plate, fixing a first portion of the optical fiber; a second fixing portion disposed on another side of the base plate, fixing a second portion of the optical fiber; and a post portion inserted into at least one hole from among the plurality of holes, the post portion routing the optical fiber on the base plate such that the optical fiber has at least one curved shape between the first portion and the second portion.

According to embodiments of the present disclosure, a light source uniformity adjusting method is provided. The light source uniformity adjusting method includes: providing a light source uniformity adjusting device that includes: a base plate that includes a plurality of holes therein, a first fixing portion on one side of the base plate, and a second fixing portion on another side of the base plate; fixing a second portion of an optical fiber to the second fixing portion; inserting a post portion into at least one hole from among the plurality of holes to route the optical fiber on the base plate such that the optical fiber including at least one curved shape; positioning a first portion of the optical fiber in the first fixing portion; checking uniformity of an image generated, the image generated using light that has passed through the optical fiber; and fixing the first portion of the optical fiber to the first fixing portion in accordance with a result of the checking the uniformity.

Aspects of the present disclosure are not limited to those mentioned above and additional aspects of the present disclosure, which are not mentioned herein, will be clearly understood by those skilled in the art from the following description of the present disclosure.

Details of other embodiments are included in the detailed description and drawings.

### BRIEF DESCRIPTION OF DRAWINGS

The above and other aspects and features of the present disclosure will become more apparent by describing in detail non-limiting example embodiments thereof with reference to the attached drawings, in which:

FIG. 1 is a view illustrating a light source device to which a light source uniformity adjusting device according to some embodiment of the present disclosure is applied;

FIG. 2 is a perspective view illustrating a light source uniformity adjusting device according to a first embodiment of the present disclosure;

FIG. 3 is a plan view illustrating the light source uniformity adjusting device according to the first embodiment of the present disclosure;

FIG. 4 is a view illustrating a shape of an optical fiber installed in the light source uniformity adjusting device of FIG. 3;

FIG. 5 is an enlarged view illustrating an area A of FIG. 4;

FIG. 6 is a cross-sectional view taken along line I-I of FIG. 4;

FIG. 7 is a cross-sectional view taken along line II-II of FIG. 4;

FIG. 8 is a view illustrating an example shape of an optical fiber implemented using a light source uniformity adjusting device according to the first embodiment of the present disclosure;

FIG. 9 is a view illustrating an example shape of an optical fiber implemented using a light source uniformity adjusting device according to the first embodiment of the present disclosure;

FIG. 10 is a view illustrating an example shape of an optical fiber implemented using a light source uniformity adjusting device according to the first embodiment of the present disclosure;

FIG. 11 is a view illustrating an example shape of an optical fiber implemented using a light source uniformity adjusting device according to the first embodiment of the present disclosure;

FIG. 12 is a plan view illustrating a light source uniformity adjusting device according to a second embodiment of the present disclosure;

FIG. 13 is a plan view illustrating a light source uniformity adjusting device according to a third embodiment of the present disclosure;

FIG. 14 is a plan view illustrating a light source uniformity adjusting device according to a fourth embodiment of the present disclosure;

FIG. 15 is a plan view illustrating a light source uniformity adjusting device according to a fifth embodiment of the present disclosure;

FIG. 16 is a flow chart illustrating a light source uniformity adjusting method according to the first embodiment of the present disclosure;

FIG. 17 is a flow chart illustrating a light source uniformity adjusting method according to the second embodiment of the present disclosure;

FIG. 18 is a flow chart illustrating a light source uniformity adjusting method according to the third embodiment of the present disclosure;

FIG. 19 is a view illustrating a wafer inspection method according to some embodiments of the present disclosure;

FIG. 20 is a block view illustrating an optical device (e.g., spectroscopic ellipsometry system) according to an embodiment of the present disclosure;

FIG. 21 is a view illustrating an image of a polarizer compensator and analyzer (PCA) angle set for a wavelength according to some embodiments of the present disclosure;

FIG. 22 is a view illustrating a spectral image for a wavelength according to some embodiments of the present disclosure;

FIG. 23 is a view illustrating a polarizer compensator and analyzer rotating (PCAR) spectral matrix according to some embodiments of the present disclosure;

FIG. 24 is a view illustrating a spectrum according to one pixel in the PCAR spectral matrix of FIG. 23;

FIG. 25 is a view illustrating a plurality of PCAR spectral matrices having different PCA angle sets; and

FIG. 26 is a view illustrating a spectrum for a specific pixel extracted from the plurality of PCAR spectral matrices of FIG. 25.

### DETAILED DESCRIPTION

Hereinafter, non-limiting example embodiments of the present disclosure will be described in detail with reference to the accompanying drawings, in which the same reference numerals are used for the substantially same elements, and a repeated description of the corresponding elements will be omitted.

It will be understood that when an element is referred to as being “over,” “above,” “on,” “below,” “under,” “beneath,” “connected to” or “coupled to” another element, it can be directly over, above, on, below, under, beneath, connected or coupled to the other element or intervening elements may be present. In contrast, when an element is referred to as being “directly over,” “directly above,” “directly on,” “directly below,” “directly under,” “directly beneath,” “directly connected to” or “directly coupled to” another element, there are no intervening elements present.

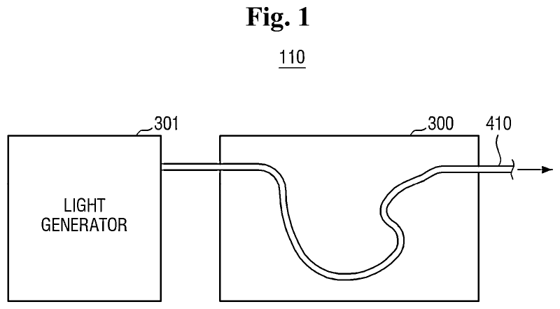

FIG. 1 is a view illustrating a light source device to which a light source uniformity adjusting device according to some embodiment of the present disclosure is applied.

Referring to FIG. 1, a light source 110 includes a light generator 301, a light source uniformity adjusting device 300, and an optical fiber 410.

Light generated by the light generator 301 is transferred through the optical fiber 410. The light generator 301 may emit broadband light. For example, the light generator 301 may irradiate visible light. In this case, a wavelength range of the visible light may be 400 nm to 800 nm, but is not limited thereto. A wavelength band of the light generator 301 may vary depending on a target to be measured, and may generally have a bandwidth from an ultraviolet (UV) band to a near-infrared (NIR) band. The light generator 301 may emit light of a specific wavelength or simultaneously emit light of various wavelengths.

The optical fiber 410 may be a multi-mode optical fiber, but is not limited thereto.

The optical fiber 410 is coiled by the light source uniformity adjusting device 300. That is, a shape of the optical fiber 410 may be variously modified by the light source uniformity adjusting device 300. The shape of the optical fiber 410 may be modified to various shapes such as a circular shape (O-type), an elliptical shape, U-type, V-type, S-type, L-type, W-type, N-type, M-type, and a polygonal shape. A worker may easily and exactly modify the shape of the optical fiber by using the light source uniformity adjusting device 300.

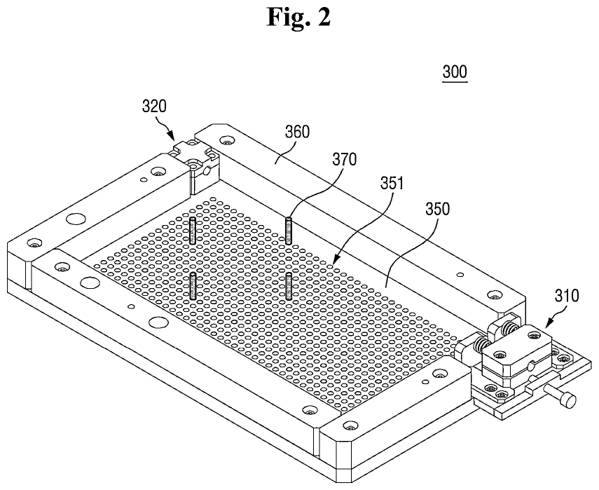

Hereinafter, the light source uniformity adjusting device 300 will be described in detail with reference to FIGS. 2 to 18.

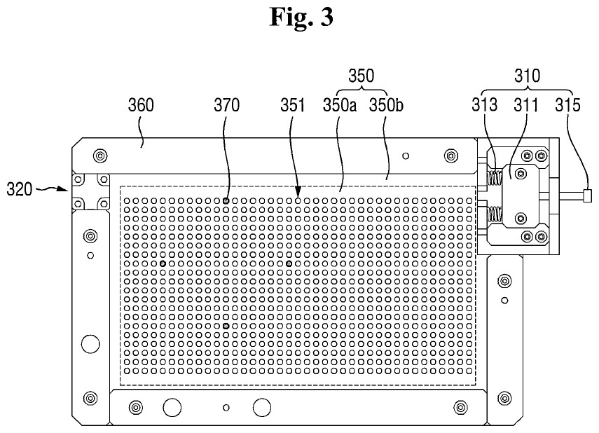

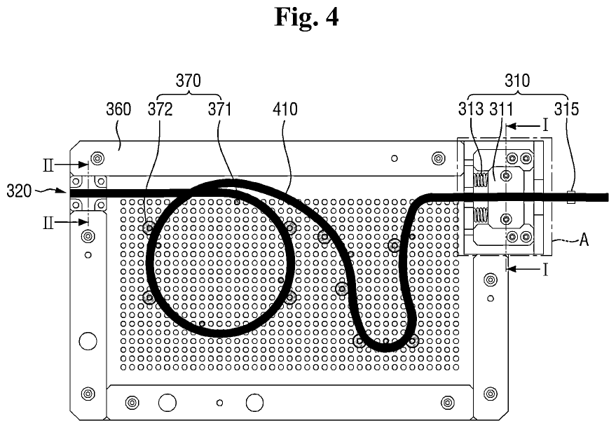

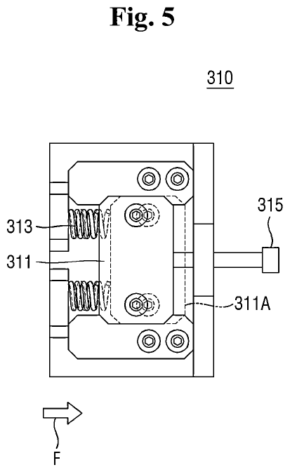

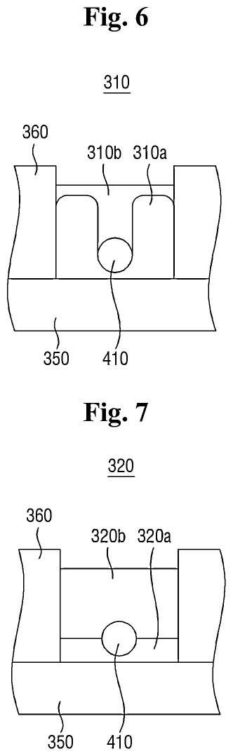

FIG. 2 is a perspective view illustrating the light source uniformity adjusting device according to the first embodiment of the present disclosure. FIG. 3 is a plan view illustrating the light source uniformity adjusting device according to the first embodiment of the present disclosure. FIG. 4 is a view illustrating a shape of an optical fiber installed in the light source uniformity adjusting device of FIG. 3. FIG. 5 is an enlarged view illustrating an area A of FIG. 4. FIG. 6 is a cross-sectional view taken along line I-I of FIG. 4. FIG. 7 is a cross-sectional view taken along line II-II of FIG. 4.

Referring to FIGS. 2 to 4, the light source uniformity adjusting device 300 according to the first embodiment of the present disclosure includes a base plate 350, a first fixing portion 310, a second fixing portion 320, a wall portion 360, and a post portion 370.

The base plate 350 may be, for example, a rectangular shape, but is not limited thereto. As shown, the base plate 350 may have a shape extended to be longer in a second direction (e.g., longitudinal direction) than a first direction (e.g., width direction). The base plate 350 may be made of metal, for example, stainless steel (SUS), aluminum, copper, or the like, but is not limited thereto.

A plurality of holes 351 are formed in the base plate 350. As shown, the plurality of holes 351 may be arranged in a matrix form. The post portion 370 is inserted into the plurality of holes 351, and the shape/position of the optical fiber 410 is fixed by the post portion 370.

The base plate 350 includes a fixing area 350a in which the plurality of holes 351 are disposed, and an edge area 350b surrounding the fixing area 350a.

The first fixing portion 310, the second fixing portion 320, and the wall portion 360 may be installed in the edge area 350b.

In detail, the first fixing portion 310 and the second fixing portion 320 correspond to an optical fiber fixing portion that holds the optical fiber for coiling without damage.

The first fixing portion 310 is installed on one side (e.g., right side in FIG. 3) of the base plate 350. The first fixing portion 310 may be installed on one side (right side) of the edge area 350b of the base plate 350.

The second fixing portion 320 is installed on the other side (e.g., left side in FIG. 3) of the base plate 350. The second fixing portion 320 may be installed on the other side (left side) of the edge area 350b of the base plate 350.

In other words, the edge area 350b includes a first edge and a second edge, which are opposite to each other, the first fixing portion 310 is installed at the first edge, and the second fixing portion is installed at the second edge.

The first fixing portion 310 fixes a first portion of the optical fiber 410, and the second fixing portion 320 fixes a second portion of the optical fiber 410. As shown in FIG. 4, the optical fiber 410 may have a curved shape between the first portion and the second portion of the optical fiber 410 by coiling.

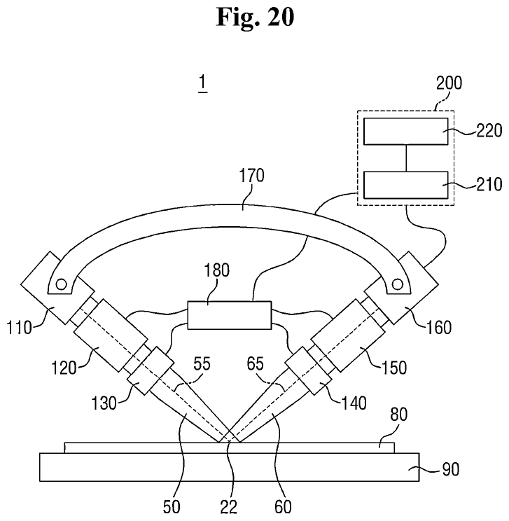

The first portion of the optical fiber 410 may be connected to the light generator 301 (refer FIG. 1), and the second portion of the optical fiber 410 may be connected to a polarizer 120 (refer to FIG. 20).

The first fixing portion 310 may include a preload device. The preload device pulls the optical fiber 410 with a preset force, thereby preventing the shape of the optical fiber 410 from being deformed by an external impact after coiling.

The first fixing portion 310 may include a fixing block 311, an elastic body 313, and an adjustment body 315. The fixing block 311 fixes the optical fiber 410 (i.e., first portion). The elastic body 313 may be, for example, a spring, and continuously provides a pushing force to the fixing block 311. Therefore, a force to be pulled is continuously provided to the optical fiber 410.

In a state that the elastic body 313 continuously provides the fixing block 311 with a pushing force, the adjustment body 315 may finely adjust a position of the fixing block 311. The adjustment body 315 may be implemented, for example, to include a screw that is connected to the fixing block 311 and is rotatable based on an axis. The position of the fixing block 311 may be adjusted in accordance with a rotation direction of the screw.

Referring to FIG. 5, when the screw is rotated in one direction, the fixing block 311 may move outwards (i.e., to the right, see arrow F) of the base plate 350 to, for example, a position 311a. When the screw is rotated in an opposite direction, the fixing block 311 may move towards an inside (i.e., to the left) of the base plate 350.

Referring to FIG. 6, the fixing block 311 includes a base 310a having a first strength and a cover 310b having a second strength smaller than the first strength. The first portion of the optical fiber 410 is fixed between the base 310a and the cover 310b.

Metal (e.g., aluminum, SUS) may be used as the base 310a to stably fix the optical fiber 410. A material such as urethane having a relatively small strength may be used as the cover 310b to prevent the optical fiber 410 fixed between the base 310a and the cover 310b from being damaged.

Referring to FIG. 7, the second fixing portion 320 includes a base 320a having a third strength and a cover 320b having a fourth strength smaller than the third strength. The second portion of optical fiber 410 is fixed between the base 320a and the cover 320b. For example, metal may be used as the base 320a, and a material such as urethane may be used as the cover 320b.

The wall portion 360 is installed in a portion of the edge area 350b, in which the first fixing portion 310 and the second fixing portion 320 are not installed.

A height of the wall portion 360 may be higher than that of the first fixing portion 310 and/or that of the second fixing portion 320, but is not limited thereto. The wall portion 360 is set up in the edge area 350b of the base plate 350, so that the optical fiber 410 disposed on the base plate 350 may be prevented from being shaken or deformed by an external impact.

Referring back to FIG. 4, the post portion 370 is inserted into at least a portion of the plurality of holes 351 of the base plate 350.

The post portion 370 routes the optical fiber 410 on the base plate 350 such that the optical fiber 410 has a curved shape between the first portion of the optical fiber 410 fixed to the first fixing portion 310 and the second portion of the optical fiber 410 fixed to the second fixing portion 320.

The post portion 370 may include a guide post 371 for guiding the shape of the optical fiber 410, and a washer 372 for pushing the optical fiber 410 toward the base plate 350 to fix the optical fiber 410. According to embodiments, only the guide post 371 may be used as the post portion 370, or only the washer 372 may be used as the post portion 370.

At least one guide post 371 and at least one washer 372 are inserted into and fixed to the holes 351.

For example, a worker may form the shape of the optical fiber 410 by using the guide post 371 and fix the optical fiber 410 by using the washer 372 so that the shape of the optical fiber 410 is not deformed.

Meanwhile, the plurality of holes 351 may be arranged on the base plate 350 in a matrix form. Coordinates may be assigned to each of the plurality of holes 351 arranged in a matrix form.

The worker may insert the guide post 371 and/or the washer 372 into a portion of the plurality of holes 351 in accordance with a previously prepared manual (or standard operating procedure (SOP)). Therefore, the worker may quickly and exactly transform the optical fiber 410 into a target shape by using the guide post 371 and/or the washer 372 inserted into an exact position even though the worker does not have a lot of work experience.

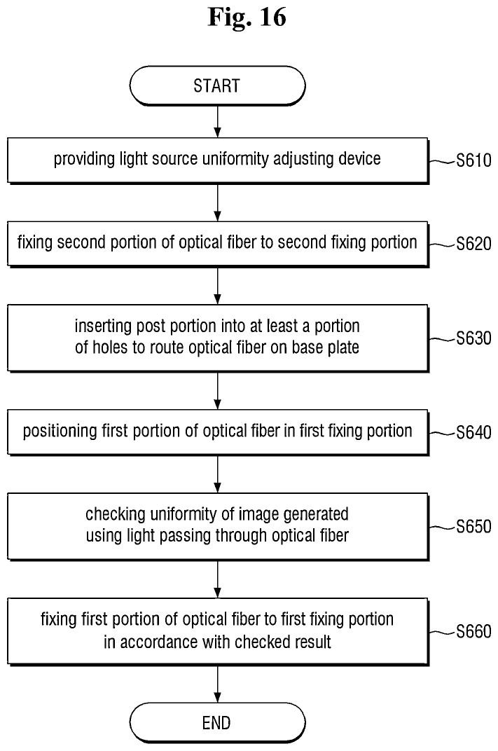

Also, even though the shape of the optical fiber 410 is completed in accordance with the manual, uniformity of an image, that is generated using light that has passed through the optical fiber 410, may not be implemented as desired. In this case, the worker may move the guide post 371 and/or the washer 372 in accordance with the state of uniformity to modify the shape of the optical fiber 410. In this way, a method of modifying the shape of the optical fiber 410 may be described in the previously prepared manual. For example, which part of the optical fiber 410 should be modified to improve side shading of an image and which part of the optical fiber 410 should be modified to improve center shading of an image may be described in the previously prepared manual. The worker modifies the shape of the optical fiber 410 until uniformity of the image is implemented to a desired degree. This will be described in detail with reference to FIGS. 16 to 18.

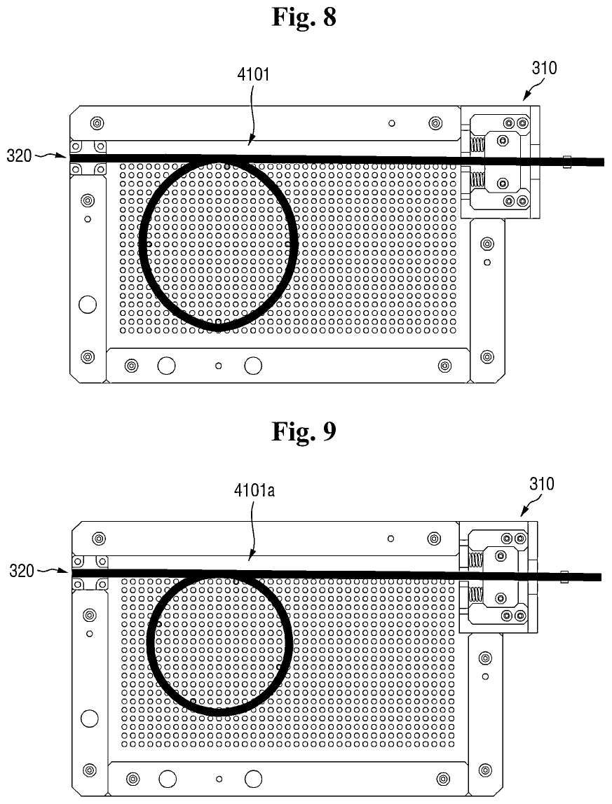

FIGS. 8 to 11 are views illustrating example shapes of an optical fiber implemented using the light source uniformity adjusting device according to the first embodiment of the present disclosure.

As shown in FIG. 8, a curved shape 4101 of the optical fiber 410 may be circular. The curved shape 4101 of the optical fiber 410 may be disposed to be closer to the second fixing portion 320 than the first fixing portion 310.

A curved shape 4101a of the optical fiber 410 shown in FIG. 9 is smaller than the curved shape 4101 of the optical fiber 410 shown in FIG. 8. A size (i.e., circular diameter) of the curved shape 4101a of the optical fiber 410 shown in FIG. 9 may be smaller than the size (i.e., circular diameter) of the curved shape 4101 of the optical fiber 410 shown in FIG. 8.

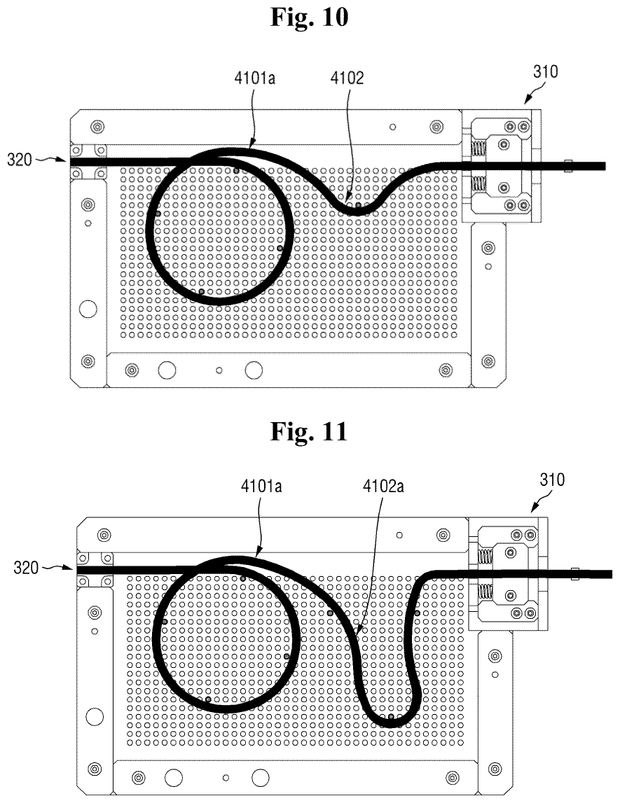

Referring to FIG. 10, a curved shape of the optical fiber 410 may include a curved shape 4101a having a circular shape, disposed to be adjacent to the second fixing portion 320, and a curved shape 4102 having a U-shape, disposed to be adjacent to the first fixing portion 310.

Referring to FIG. 11, a curved shape of the optical fiber 410 may include a curved shape 4101a having a circular shape, disposed to be adjacent to the second fixing portion 320, and a first curved shape 4102a having a U-shape, disposed to be adjacent to the first fixing portion 310. A depth (i.e., depth of a concave U-type shape) of the first curved shape 4102a shown in FIG. 11 may be deeper than that (i.e., depth of a concave U-type shape) of the curved shape 4102 shown in FIG. 10.

For example, when the curved shape 4101 of the optical fiber 410 is formed in a circular shape as shown in FIG. 8 but uniformity of an image is not implemented as much as desired, the worker may modify the circular diameter to a small size as shown in FIG. 9 (see curved shape 4101a).

In addition, when the curved shape 4101a of the optical fiber 410 is formed in a circular shape as shown in FIG. 9 but uniformity of the image is not implemented as desired, the worker may add a U-type shape (i.e., the curved shape 4102) as shown in FIG. 10.

For example, when the curved shape 4101a and the curved shape 4102 of the optical fiber 410 are formed as shown in FIG. 10 but uniformity of the image is not implemented as desired, the worker may deeply modify the depth of the first curved shape 4102a as shown in FIG. 11.

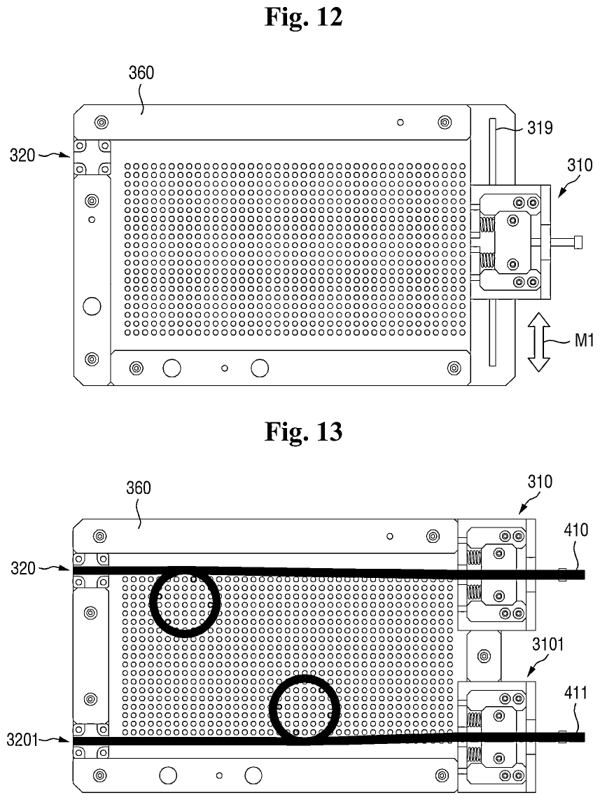

FIG. 12 is a plan view illustrating a light source uniformity adjusting device according to a second embodiment of the present disclosure. For convenience of description, the description will be based on a difference from the description made with reference to FIGS. 2 to 11.

Referring to FIG. 12, a rail 319 is disposed along the edge area 350b (refer to FIG. 3) (e.g., right edge of the base plate 350) of the base plate 350 (refer to FIG. 3), and the first fixing portion 310 is movable along the rail 319 (see arrows Ml). When the first fixing portion 310 is movable, the curved shape of the optical fiber 410 may be implemented in various forms.

FIG. 13 is a plan view illustrating a light source uniformity adjusting device according to a third embodiment of the present disclosure. For convenience of description, the description will be based on a difference from the description made with reference to FIGS. 2 to 11.

Referring to FIG. 13, a plurality of first fixing portions 310 and 3101 are disposed on one side (e.g., right edge of the base plate 350) of the base plate 350 (refer to FIG. 3).

A plurality of second fixing portions 320 and 3201 are disposed on the other side (e.g., left edge of the base plate 350) of the base plate 350.

When a plurality of first fixing portions 310 and 3101 and second fixing portions 320 and 3201 are installed in one base plate 350, coiling of a plurality of optical fibers 410 may be performed using one base plate 350. As shown, coiling of the optical fiber 410 may be performed using a pair of the first fixing portion 310 and the second fixing portion 320, and coiling of another one of the optical fiber 411 may be performed using another pair of the first fixing portion 3101 and the second fixing portion 3201.

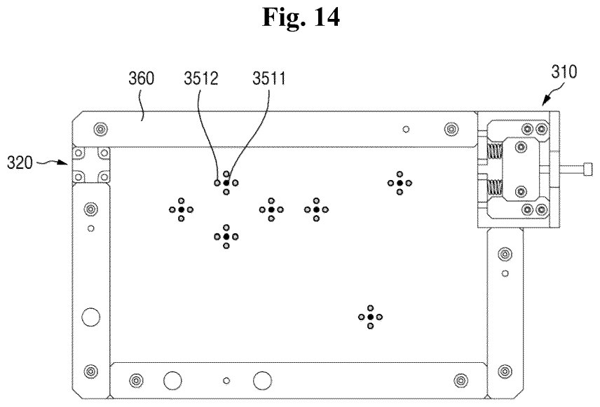

FIG. 14 is a plan view illustrating a light source uniformity adjusting device according to a fourth embodiment of the present disclosure. For convenience of description, the description will be based on a difference from the description made with reference to FIGS. 2 to 11.

In FIG. 3, the plurality of holes 351 are installed in the base plate 350 in a matrix form.

On the other hand, in FIG. 14, a plurality of holes are installed in a predetermined position of the base plate 350. In particular, a plurality of reference holes 3511 are installed in the base plate 350 (refer to FIG. 3), and at least one adjustment hole 3512 is installed to be adjacent to each of the plurality of reference holes 3511.

For example, the worker may first install the post portion 370 (refer to FIG. 3) in the plurality of reference holes 3511, and may move the post portion 370 to the adjustment hole 3512 adjacent to one of the reference holes 3511 when uniformity of the image is not implemented as desired.

When the plurality of holes (e.g., the reference holes 3511 and the at least one adjustment hole 3512) are installed in the base plate 350 as above, the installation degree of freedom of the post portion 370 may be reduced as compared with the case that the plurality of holes 351 are installed in the base plate 350 in a matrix form, but the worker may intuitively and quickly change the position of the post portion 370.

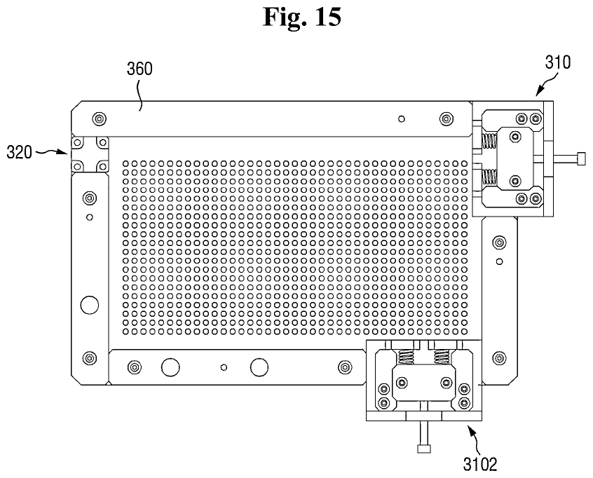

FIG. 15 is a plan view illustrating a light source uniformity adjusting device according to a fifth embodiment of the present disclosure. For convenience of description, the description will be based on a difference from the description made with reference to FIGS. 2 to 11.

Referring to FIG. 15, in the light source uniformity adjusting device according to the fifth embodiment of the present disclosure, the plurality of first fixing portions 310 and 3102 are installed in the edge area 350b (refer to FIG. 3) of the base plate 350 (refer to FIG. 3). An edge (e.g., right edge) in which the first fixing portion 310 is installed may be different from an edge (e.g., lower edge) in which the first fixing portion 3102 is installed.

When the number of the first fixing portions 310 and 3102 is greater than the number of the second fixing portion 320, only the first fixing portion (e.g., first fixing portion 3102) selected from the plurality of first fixing portions 310 and 3102 is used. For example, the first portion of the optical fiber 410 is fixed to the first fixing portion 3102, and the second portion of the optical fiber 410 is fixed to the second fixing portion 320. The first fixing portion 310 may not be used.

FIG. 16 is a flow chart illustrating a light source uniformity adjusting method according to the first embodiment of the present disclosure. For convenience of description, the method will be described using the light source uniformity adjusting device shown in FIGS. 2 to 4.

Referring to FIG. 16, the light source uniformity adjusting device is provided (S610).

In detail, as shown in FIGS. 2 to 4, the light source uniformity adjusting device 300 includes a base plate 350 having a plurality of holes 351, a first fixing portion 310 disposed on one side of the base plate 350, fixing a first portion of the optical fiber 410, and a second fixing portion 320 disposed on the other side of the base plate 350, fixing a second portion of the optical fiber 410. The second fixing portion 320 is a preload device.

Subsequently, the second portion of the optical fiber is fixed to the second fixing portion 320 (S620).

Subsequently, the post portion 370 is inserted into at least a portion of the plurality of holes 351 to route the optical fiber 410 on the base plate 350 (S630). In detail, the worker inserts the post portion 370 into several holes 351, and may use them to form a curved shape of the optical fiber 410. The curved shape of the optical fiber 410 may be a circular shape (O-type), an elliptical shape, U-type, V-type, S-type, L-type, W-type, N-type, M-type, and a polygonal shape.

Subsequently, the first portion of the optical fiber 410 is positioned in the first fixing portion 310 (S640). In this case, the first portion of the optical fiber 410 is only disposed to pass through the first fixing portion 310 (i.e., the preload device), and the first portion is not completely fixed by the first fixing portion 310.

Subsequently, uniformity of an image generated using light passing through the optical fiber is checked (S650).

In detail, it is checked whether uniformity of the image is implemented as desired. As a method for checking uniformity of the image, the worker may check uniformity with eyes while viewing a live image, or may check uniformity by using an image analysis program.

Subsequently, the first portion of the optical fiber 410 is fixed to the first fixing portion 310 in accordance with the checked result (S660).

As a result of checking, when uniformity of the image is implemented as desired, the first portion of the optical fiber 410 is completely fixed to the first fixing portion 310 so that the optical fiber 410 does not move.

On the other hand, when uniformity of the image is not implemented as desired, the worker moves the post portion 370 to modify the curved shape of the optical fiber 410.

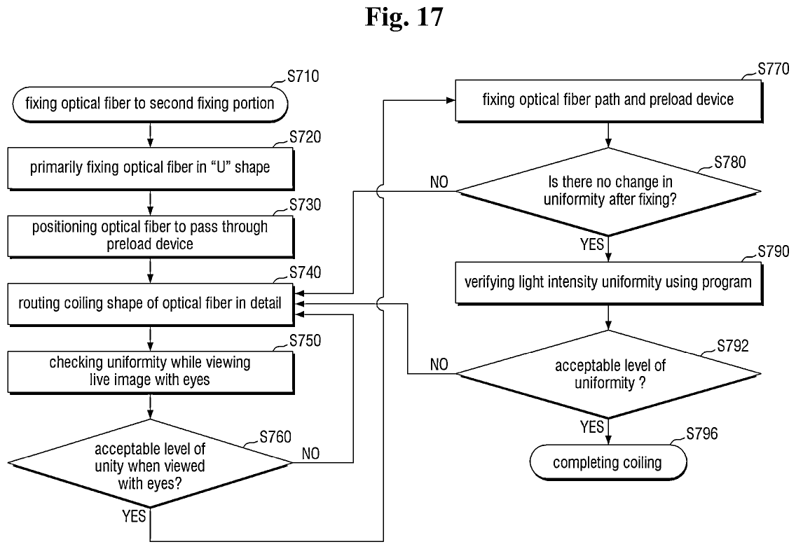

FIG. 17 is a flow chart illustrating a light source uniformity adjusting method according to the second embodiment of the present disclosure. For convenience of description, the method will be described using the light source uniformity adjusting device shown in FIGS. 2 to 4.

Referring to FIG. 17, the optical fiber 410 passes through the second fixing portion 320 of the light source uniformity adjusting device 300 to fix the second portion of the optical fiber 410 to the second fixing portion 320 (S710).

Subsequently, after the optical fiber 410 on the base plate 350 is transformed into a U-shape, the optical fiber 410 is primarily fixed to the base plate 350 (S720).

Subsequently, the optical fiber 410 is positioned so that the optical fiber 410 passes through the first fixing portion 310 (i.e., the preload device) of the light source uniformity adjusting device 300 (S730).

Subsequently, a coiling shape of the optical fiber 410 is routing in detail (S720). For example, an angle of the U-shape formed in the step S720 may be changed in detail, or a depth of the U-shape (concave trench shape) may be changed in detail.

Subsequently, the worker checks uniformity with eyes while viewing a live image (S750). That is, the worker checks whether the image is uniform, while viewing the image generated based on the light that has passed through the optical fiber 410 that is routed in detail.

When there is not an acceptable level of uniformity (NO of S760) after checking uniformity with eyes, the current step returns to the step S740 of routing the coiling shape of the optical fiber 410 in detail.

On the other hand, when there is an acceptable level of uniformity (YES of S760), a path (i.e., coiling shape) of the optical fiber 410 is fixed, and the second fixing portion 320 (i.e., the preload device) fixes the optical fiber 410 (S770).

Subsequently, after the optical fiber 410 is fixed by the second fixing portion 320, it is checked whether there is any change in uniformity of the image (S780).

When there is any change in uniformity of the image (NO of S780), the current step returns to the step S740 of routing the coiling shape of the optical fiber 410 in detail.

When there is no change in uniformity of the image (YES of S780), uniformity (light intensity uniformity) of the image is verified using a program (S790).

As a result of verification, when the verified result does not indicate an acceptable level of uniformity (NO of S792), the current step returns to the step S740 of routing the coiling shape of the optical fiber 410 in detail.

When the verified result indicates an acceptable level of uniformity (YES of S792), the coiling task is completed (S796).

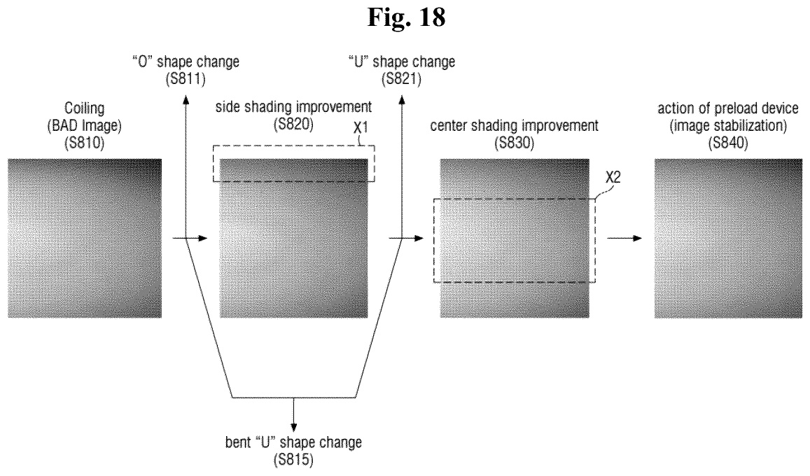

FIG. 18 is a flow chart illustrating a light source uniformity adjusting method according to the third embodiment of the present disclosure. FIG. 18 is a view illustrating a method of routing a shape of an optical fiber in detail in accordance with uniformity of an image.

Referring to FIG. 18, coiling of the optical fiber 410 is primarily performed. For example, a shape of the optical fiber 410 for which coiling is primarily performed may be as shown in FIG. 10. That is, the shape of the optical fiber 410 may have an O-type shape and a U-type shape.

Subsequently, as a result of checking uniformity of the image, uniformity of the image is not good (S810).

Subsequently, the O-type shape from the shape of the optical fiber 410 is changed (S811).

Subsequently, as a result of checking uniformity of the image, it is noted that side shading (see area X1) of the image has been improved (S820).

Subsequently, the U-type shape among the shapes of the optical fiber 410 is changed (S811).

Subsequently, as a result of checking uniformity of the image, it is noted that center shading (see area X2) of the image has been also improved (S830).

Since uniformity of the image is within a reference value, the optical fiber 410 is fixed using the first fixing portion 310 (i.e., the preload device) (S840). Therefore, uniformity of the image is stabilized.

Meanwhile, it has been described that the O-type shape among the shapes of the optical fiber 410 is changed to improve side shading (see S811) and the U-type shape among the shape of the optical fiber 410 is changed to improve center shading (see S821), but embodiments of the present disclosure are not limited thereto.

For example, when the shape of the optical fiber 410 for which coiling is primarily performed is U-shape, both side shading and center shading may be improved by changing the U-shape in detail (see S815).

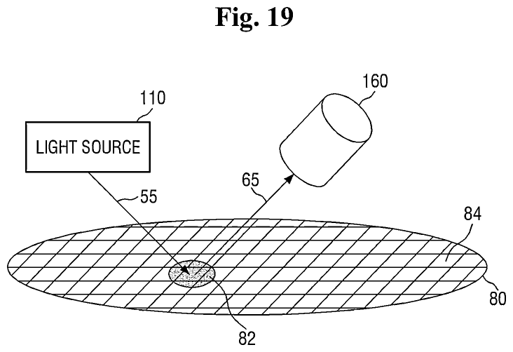

An optical device (e.g., spectroscopic ellipsometry system) using the above-described light source uniformity adjusting device will be described with reference to FIGS. 19 to 26.

FIG. 19 is a view illustrating a wafer inspection method according to some embodiments of the present disclosure.

Referring to FIG. 19, the wafer inspection method according to some embodiments of the present disclosure may inspect a wafer 80 by using a spectral image sensing method.

First of all, incident light 55 is irradiated from a light source 110 to a measurement area 82 on the wafer 80. A manufacturing process may be performed on the wafer 80 to form a plurality of areas, e.g., chip areas 84. The measurement area 82 may be one of the chip areas 84 or a plurality of the chip areas 84 depending on the range of irradiating the incident light 55. The wafer inspection method according to some embodiments of the present disclosure may measure spectral ellipsometry (SE) data for a plurality of positions at once. The light source 110 may include a light generator 301 (refer to FIG. 1), an optical fiber 410 (refer to FIG. 1), and a light source uniformity adjusting device 300 (refer to FIG. 1).

The incident light 55 irradiated to the wafer 80 may be reflected from the measurement area 82 on the wafer 80, and reflective light 65 reflected from the measurement area 82 may be incident on a detector 160. The detector 160 may be, for example, a spectral imaging camera, but embodiments of the present disclosure are not limited thereto. The detector 160 may detect a spectral image from the incident reflective light 65. The detector 160 will be described in detail later.

FIG. 20 is a block view illustrating an optical device (e.g., spectroscopic ellipsometry system) according to an embodiment of the present disclosure.

Referring to FIG. 20, the spectroscopic ellipsometry system 1 according to one embodiment of the present disclosure includes a wafer 80, a tray 90, a light source 110, a polarizer 120, a compensator 130, an analyzer 140, an imaging lens 150, a detector 160, a controller 180, an angle handler 170, and a processor 200.

The wafer 80 may include the measurement area 82 (refer to FIG. 19). The wafer 80 may be a semiconductor substrate. Such a substrate may include silicon (Si), strained silicon (Si), silicon alloys, silicon carbide (SiC), silicon germanium (SiGe), silicon germanium carbide (SiGeC), germanium, germanium alloys, gallium arsenide (GaAs), indium arsenide (InAs), and one of III-V semiconductors and II-VI semiconductors, combinations thereof, and laminates thereof. Alternatively, the wafer 80 may be an organic plastic substrate that is not a semiconductor substrate. The wafer 80 may be positioned on the tray 90.

The tray 90 may be provided with the wafer 80 seated thereon. The tray 90 may fix a position of the wafer 80 during a semiconductor process, or may move the wafer 80 to a particular position. For example, the tray 90 may move the wafer 80 in a first direction or a second direction orthogonal to the first direction, but embodiments of the present disclosure are not limited thereto.

The light source 110 may include a light generator 301 (refer to FIG. 1), an optical fiber 410 (refer to FIG. 1), and a light source uniformity adjusting device 300 (refer to FIG. 1).

The polarizer 120 or the compensator 130 may be disposed on a path of the incident light 55 emitted from the light source 110, and the incident light 55 may move within an incident body 50. That is, the incident light 55 may be irradiated to the measurement area 82 (refer to FIG. 19) of the wafer 80 placed on the tray 90 via the polarizer 120 or the compensator 130. A wavelength range of the light source 110 may be associated with the detector 160. Since sensitivity of the light source 110 to the measurement area 82 on the wafer 80 is different depending the wavelength range of the light source 110, wavelength bands of various ranges may be used, but embodiments of the present disclosure are not limited thereto.

The incident body 50 may fix positions of the light source 110, the polarizer 120, and the compensator 130, and may be formed to be extended in the same direction as the path of the incident light 55.

The polarizer 120 may adjust a polarization direction of the incident light 55. According to embodiments, the polarizer 120 includes a rotating portion capable of adjusting the polarization direction, and may rotate at a first angle. The polarizer 120 may receive the incident light 55 from the light source 110. The polarizer 120 may be electrically connected to the controller 180. The controller 180 may adjust the first angle of the polarizer 120.

The compensator 130 may adjust a phase difference of the incident light 55. According to embodiments, the compensator 130 includes a rotating portion, and may rotate at a second angle. The compensator 130 may adjust the phase difference of the incident light 55 by using the rotating portion. The compensator 130 may be electrically connected to the controller 180. The controller 180 may adjust the second angle of the compensator 130. The compensator 130 may be connected to the light source 110 or the polarizer 120 through the incident body 50.

The incident light 55 generated from the light source 110 may be irradiated to a measurement sample 22 on the wafer 80, and the reflective light 65 reflected in the measurement sample 22 may move within an emission body 60.

The emission body 60 may fix the positions of the analyzer 140, the imaging lens 150, and the detector 160, and may be formed to be extended in the same direction as the path of the reflective light 65. The incident angle of the incident light 55 and a reflective angle of the reflective light 65 may be the same as each other, but embodiments of the present disclosure are not limited thereto.

The analyzer 140 may adjust the polarization direction of the reflective light 65 reflected in the measurement sample 22. According to embodiments, the analyzer 140 includes a rotating portion, and may rotate at a third angle. The analyzer 140 may be electrically connected to the controller 180. The controller 180 may adjust the third angle of the analyzer 140.

The imaging lens 150 may adjust chromatic aberration of the reflective light 65. The imaging lens 150 may be disposed between the analyzer 140 and the detector 160. The imaging lens 150 has a focal distance (f), which may be inversely proportional to a distance between the imaging lens 150 and the measurement sample 22, and may be proportional to a distance between the imaging lens 150 and the detector 160, but embodiments of the present disclosure are not limited thereto. The imaging lens 150 may be also connected to the controller 180, and the controller 180 may change a position of the imaging lens 150 to adjust the focal distance (f), but embodiments of the present disclosure are not limited thereto.

The detector 160 may detect a spectral image from the reflective light 65. For example, the detector 160 may detect a spectral image for a particular wavelength. According to embodiments, the detector 160 may include an optical sensor capable of sensing the reflective light 65. The reflective light 65 incident on the optical sensor may be incident at a first angle, and the first angle may not be perpendicular, but embodiments of the present disclosure are not limited thereto.

The angle handler 170 may adjust the incident angle of the incident light 55 and the reflective angle of the reflective light 65. In detail, the angle handler 170 may be connected to one side of the incident body 50 and one side of the emission body 60. The angle handler 170 may adjust the angle of the incident body 50 and the emission body 60. According to embodiments, the angle handler 170 may be controlled by the controller 180 or the processor 200, but embodiments of the present disclosure are not limited thereto.

The controller 180 may be connected to the polarizer 120, the compensator 130, the analyzer 140, the imaging lens 150, and the processor 200. The controller 180 may receive a PCA angle set from the processor 200. The PCA angle set may include first to third angles. The controller 180 may control the first angle of the polarizer 120, the second angle of the compensator 130, and the third angle of the analyzer 140 in accordance with the received PCA angle set, but embodiments of the present disclosure are not limited thereto, and the controller 180 may change the first to third angles in accordance with a predetermined value to generate the PCA angle set. For example, after setting the first angle and the third angle of the polarizer 120 and the analyzer 140, the controller 180 may generate a plurality of PCA angle sets while changing the second angle of the compensator 130.

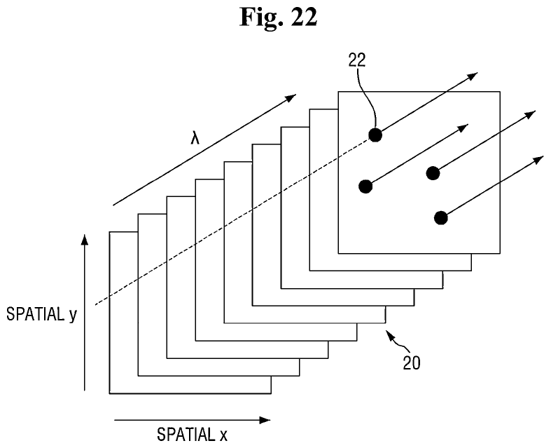

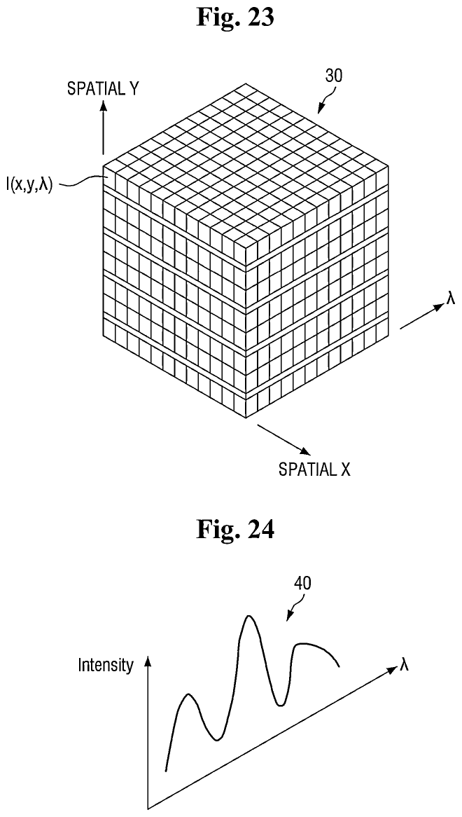

The processor 200 may receive a spectral image 20 (refer to FIG. 22) from the detector 160. The processor 200 may generate a polarizer compensator and analyzer rotating (PCAR) spectral matrix 30 (refer to FIG. 23) by using the received spectral image 20 (refer to FIG. 22). For example, the processor 200 may receive a first spectral image corresponding to a first PCA angle set and a first wavelength, and may further receive a second spectral image corresponding to a second PCA angle set and a second wavelength different from the first wavelength from the detector 160, and may generate the PCAR spectral matrix 30 (refer to FIG. 23) by using the first and second spectral images, but embodiments of the present disclosure are not limited thereto. The detector 160 may be a spectral imaging camera.

In detail, the processor 200 may include a first processing unit 210 and a second processing unit 220, but embodiments of the present disclosure are not limited thereto. Although FIG. 20 illustrates that the processor 200 includes the first processing unit 210 and the second processing unit 220, the second processing unit 220 may be configured to be separated from the first processing unit 210.

The first processing unit 210 may convert the first and second spectral images detected from the detector 160 into the PCAR spectral matrix 30 (refer to FIG. 23) and store the converted PCAR spectral matrix. The PCAR spectral matrix 30 (refer to FIG. 23) will be described in detail later. The first processing unit 210 may generate a spectrum 40 (refer to FIG. 24) indicating a change in light intensity according to a wavelength in each pixel by using the PCAR spectral matrix 30 (refer to FIG. 23). The first processing unit 210 may be connected to the second processing unit 220, and may perform a generation operation of the spectrum 40 (refer to FIG. 24) when there is a request of the second processing unit 220. The first processing unit 210 may be a data readout computer, but embodiments of the present disclosure are not limited thereto.

The second processing unit 220 may analyze the spectrum 40 (refer to FIG. 24) generated by the first processing unit 210 to select a PCA angle set and a wavelength band of an optimal condition for a measurement parameter. The second processing unit 220 may be an optical critical dimension (OCD) meter that includes a spectrum recognition algorithm or the analyzer 140 (also referred to as a data analyzer). The optical critical dimension meter may extract physical parameters of an inspection area of the wafer 80 from spectral data. The spectrum recognition algorithm of the optical critical dimension meter may utilize a Rigorous Coupled-Wave Analysis (RCWA) algorithm. The Rigorous Coupled-Wave Analysis algorithm may be usefully used to describe diffraction or reflection of electromagnetic waves from a surface of a grid structure, but embodiments of the present disclosure are not limited thereto. The second processing unit 220 may be configured to perform a spectroscopic image ellipsometry analysis technique, a multi-point high-speed measurement spectroscopic ellipsometry analysis technique, and the like for profile change tendency monitoring in the wafer 80. In addition, the second processing unit 220 may perform a variable separation algorithm such as a correlation analysis algorithm, a principal component analysis algorithm, and a rank test to extract a profile change value from a plurality of spectra. The algorithms will be described in detail later.

Measurement parameters that may be measured by the spectroscopic ellipsometry system 1 may include critical dimension, pattern height, recess, overlay, or defect.

The spectroscopic ellipsometry system 1 according to some embodiments of the present disclosure may find a PCA angle set and a wavelength band of an optimal condition, which most sensitively react to a measurement parameter to be measured. The spectroscopic ellipsometry system 1 may obtain a PCA angle set and a wavelength band of an optimal condition for each measurement parameter, and then may use the obtained PCA angle set and wavelength band for measurement parameter monitoring to check whether a value of the measurement parameter is changed, at high speed.

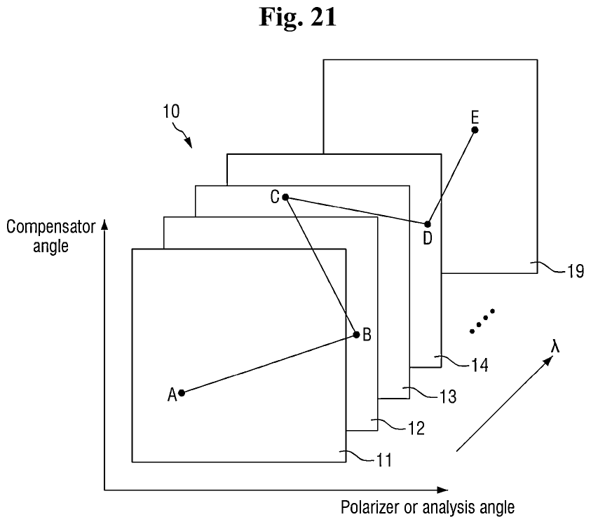

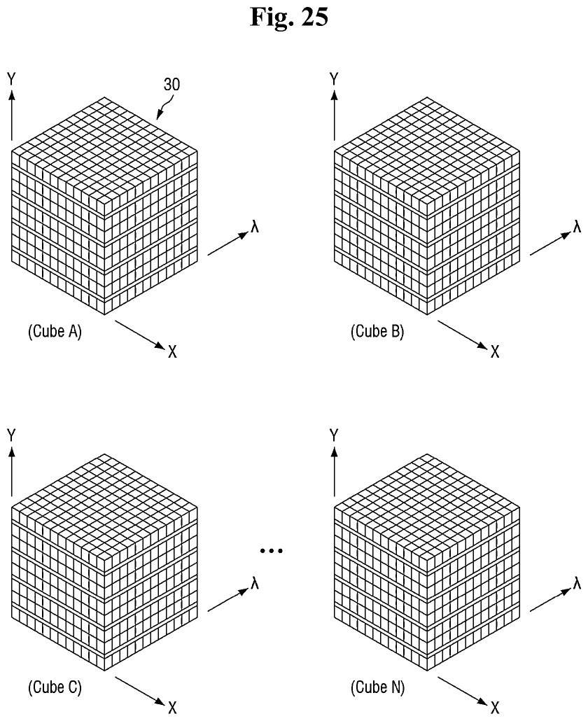

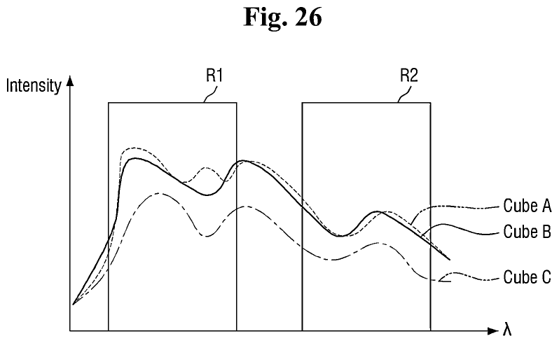

FIG. 21 is a view illustrating an image of a PCA angle set for a wavelength according to some embodiments of the present disclosure. FIG. 22 is a view illustrating a spectral image for a wavelength according to some embodiments of the present disclosure. FIG. 23 is a view illustrating a PCAR spectral matrix according to some embodiments of the present disclosure. FIG. 24 is a view illustrating a spectrum according to one pixel in the PCAR spectral matrix of FIG. 23. FIG. 25 is a view illustrating a plurality of PCAR spectral matrices having different PCA angle sets. FIG. 26 is a view illustrating a spectrum for a specific pixel extracted from the plurality of PCAR spectral matrices of FIG. 25.

In the spectroscopic ellipsometry system 1 according to some embodiments of the present disclosure, when light having a polarization component passes through the measurement sample 22, reflectance and phase values are changed depending on a polarization direction (e.g., p-wave, s-wave). The spectroscopic ellipsometry system 1 measures electromagnetic field values of the p-wave and the s-wave by changing a combination of the PCA angle set. The first angle of the polarizer 120 may determine a polarization direction of light incident on a sample, and the second angle of the compensator 130 may determine a phase difference between the p-wave and the s-wave. The third angle of the analyzer 140 may determine the polarization direction of the light incident on the detector 160 after passing through the sample.

When a pattern profile at a measurement position is changed due to a process change or occurrence of a defect of a semiconductor device, reflectance and phase values of the measurement sample 22 are changed. At this time, when the PCA angle set is changed, a profile change tendency of a pattern may be detected. When the measurement sample 22 has a complex structure, a change value for the measurement parameter may complexly affect reflectance and the phase difference in the measurement area 82. Therefore, a PCA angle set that is most sensitively affected by the variation of the measurement parameter may be required. However, since there is limitation in separation of parameters of sufficient sensitivity by only the PCA angle set, spectral data for each PCA angle set utilizing the spectroscopic ellipsometry analysis technique may be used. Since reflectance and the phase difference of the p-wave and the s-wave for each wavelength vary depending on the measurement parameter, when spectral data are used, more measurement parameters may be separated.

Referring to FIG. 21, the spectroscopic ellipsometry system 1 according to some embodiments of the present disclosure may select a PCA angle set for each wavelength for a first measurement parameter. For example, different PCA angle sets A, B, C, D and E may be selected for each wavelength (k). The PCA angle set may be selected randomly, depending on a predetermined order, or using a PCA angle set selection algorithm, but embodiments of the present disclosure are not limited thereto.

Referring to FIG. 22, each spectral image 20 may be measured for each PCA angle set. The spectral image 20 may be comprised of data for spatial coordinates x (spatial x) and spatial coordinates y (spatial y). The PCA angle set may be selected for each wavelength, and spectral images 20 corresponding to the wavelength and the PCA angle set may be measured, respectively. For example, n number of spectral images 20 may be measured for n wavelengths (k), and the PCA angle sets of the spectral images 20 may be different from each other, but embodiments of the present disclosure are not limited thereto.

Referring to FIG. 23, FIG. 23 illustrates a PCAR spectral matrix 30. The PCAR spectral matrix 30 may be formed by the processor 200 by using the plurality of spectral images 20, but embodiments of the present disclosure are not limited thereto. The reflective light 65 may be measured by the detector 160, so that the PCAR spectral matrix 30 may be directly obtained by the detector 160, and the PCAR spectral matrix 30 output from the detector 160 may be stored in the first processing unit 210 of the processor 200.

The PCAR spectral matrix 30 refers to a virtual spectral data structure obtained through a pixel re-sampling process of a spatial area and a spectrum area. The PCAR spectral matrix 30 may be referred to as a spectral cube. The PCAR spectral matrix 30 includes spatial coordinates, i.e., spatial X and spatial Y as shown in FIG. 23, and may include a plurality of spectral images 20 according to wavelength (λ) as a width. That is, the PCAR spectral matrix 30 may be comprised of data in the form of a spectral cube having spatial coordinate x, spatial coordinate y, and a wavelength λ for the pixel array of the measurement sample 22 as coordinate axes.

The PCAR spectral matrix 30 may be referred to as a coordinate I (x, y, λ). The spectral image 20 may be referred to as a spectral domain. The PCAR spectral matrix 30 may include spectral images 20 having spatial coordinates of each pixel (e.g., measurement sample 22), which are taken by a field of view (FOV) of the optical sensor included in the detector 160, and a spectrum of each pixel 24 according to the wavelength. That is, the PCAR spectral matrix 30 may include a plurality of spectral images 20 and a spectrum representing a change in light intensity according to the wavelength in each pixel of the spectral images 20.

Referring to FIG. 24, FIG. 24 illustrates a spectrum representing a change in light intensity according to the wavelength of the reflective light 65 of the spectral images 20 according to one pixel (e.g., one measurement sample), as indicated by arrows shown in FIG. 22. In FIG. 24, y-axis represents light intensity, and z-axis represents the wavelength.

Referring to FIG. 25, the spectroscopic ellipsometry system 1 according to some embodiments of the present disclosure forms a plurality of PCAR spectral matrices 30 for one measurement sample 22. The PCAR spectral matrices 30 may be formed by the processor 200 or the detector 160. The respective PCAR spectral matrices 30 may be formed through substantially the same method (described with reference to FIGS. 21 to 24). The respective PCAR spectral matrices 30 may have the same data structure. For example, N number of PCAR spectral matrices 30 may be generated for one measurement sample 22, but embodiments of the present disclosure are not limited thereto.

The plurality of PCAR spectral matrices 30 may be sequentially generated. However, when the respective PCAR spectral matrices 30 are generated, the PCA angle set may be determined randomly or using a predetermined algorithm. That is, the respective PCAR spectral matrices 30 may have combination of different PCA angle sets.

In detail, a first one of the PCAR spectral matrix 30 and a second one of the PCAR spectral matrix 30 may have the same number of spectral images 20. However, the PCA angle set of a first one of the spectral image 20 of the first wavelength included in the first one of the PCAR spectral matrix 30 may be different from the PCA angle set of the second spectral image of the first wavelength included in the second one of the PCAR spectral matrix 30. For example, the first processing unit 210 may store the first one of the PCAR spectral matrix 30 and the second one of the PCAR spectral matrix 30 different from the first one of the PCAR spectral matrix 30, wherein the first one of the PCAR spectral matrix 30 may be generated using the first and second spectral images, and the second one of the PCAR spectral matrix 30 may be generated using a third spectral image corresponding to a third PCA angle set different from the first PCA angle set and the first wavelength and a fourth one of the spectral image 20 corresponding to a fourth PCA angle set different from the second PCA angle set and the second wavelength, but embodiments of the present disclosure are not limited thereto.

The spectroscopic ellipsometry system 1 according to some embodiments of the present disclosure may select a PCAR spectral matrix 30, which varies most sensitively to the measurement parameter, among the plurality of measured PCAR spectral matrices 30 that are measured.

Referring to FIG. 26, FIG. 26 illustrates a spectrum for a first pixel of the measurement sample 22. The second processing unit 220 may extract the spectrum for the first pixel from the plurality of PCAR spectral matrices 30, respectively, and may compare the extracted spectra with each other. The second processing unit 220 may select a PCA angle set and a wavelength band (e.g., R1 or R2) of an optimal condition, which are most sensitive to the measurement parameter, among the spectra shown in FIG. 26. All of the spectra of Cubes A to C shown in FIG. 26 may have their respective PCA angle sets different from one another, but embodiments of the present disclosure are not limited thereto.

The second processing unit 220 may perform a variable separation algorithm such as a correlation analysis algorithm, a principal component analysis algorithm, and a rank test to extract a profile change value from a plurality of spectra.

The correlation analysis algorithm may measure similarity between the spectra (e.g., S1 and S2) extracted from the PCAR spectral matrix 30 and an ideal spectral value (e.g., Sref). The ideal spectral value (e.g., Sref) corresponds to a value previously determined by a user for the measurement sample 22. That is, the measurement sample 22 may be manufactured by a user to fulfil the ideal spectral value (e.g., Sref). The measurement sample 22 may vary depending on the measurement parameter to be measured, but embodiments of the present disclosure are not limited thereto. A plurality of measurement parameters may be handled by one measurement sample 22.

The principal component analysis algorithm may preferentially select a wavelength band having the largest displacement of the measurement parameter within the extracted spectrum.

When various measurement parameters represent optimal sensitivity at the same condition with respect to the selected PCA angle set and wavelength band, the condition may be finely adjusted to select an independent final condition for each of the measurement parameters. In this case, a rank test may be used.

The rank test may determine whether the PCA angle set and the wavelength band of the optimal condition overlap each other among the plurality of measurement parameters. When the PCA angle set and the wavelength band of the optimal condition overlap each other, measurement may not be performed normally by interference between the measurement parameters. In this case, the correlation analysis algorithm or the principal component analysis algorithm may be performed to select a PCA angle set and a wavelength band of next order to prevent interference between the plurality of measurement parameters from occurring.

When the selected PCA angle set and wavelength band of the optimal condition are used, the spectral image for different wafers may be measured to detect local distribution and defects for each measurement parameter of profiles in the image at high speed.

According to embodiments of the present disclosure, at least one from among the controller 180, the processor 200, and the detector 160 may include at least one computer processor and memory storing computer instructions that, when executed by the at least one computer processor, are configured to cause the controller 180, the processor 200, or the detector 160 to perform its functions described in the present disclosure.

Although non-limiting example embodiments of the present disclosure have been described with reference to the accompanying drawings, embodiments of the present disclosure can be various forms without being limited to the above-described embodiments, and the person with ordinary skill in the art to which the present disclosure pertains can understand that embodiments of the present disclosure can be embodied in other specific forms without departing from technical spirits and characteristics of the present disclosure. Thus, the above example embodiments are to be considered in all respects as illustrative and not restrictive.

What is claimed is:

1. A light source uniformity adjusting device comprising:
a base plate comprising a plurality of holes therein;
a first fixing portion on one side of the base plate, fixing a first portion of an optical fiber;
a second fixing portion disposed on another side of the base plate, fixing a second portion of the optical fiber; and
a post portion inserted into at least one hole from among the plurality of holes, the post portion routing the optical fiber on the base plate such that the optical fiber has at least one curved shape between the first portion and the second portion.

2. The light source uniformity adjusting device of claim 1, wherein the first fixing portion comprises a preload device.

3. The light source uniformity adjusting device of claim 2, wherein the preload device comprises:
a fixing block fixing the first portion of the optical fiber;
an elastic body continuously providing a pushing force to the fixing block; and
an adjustment body configured to adjust a position of the fixing block.

4. The light source uniformity adjusting device of claim 3, wherein the fixing block comprises a base having a first strength and a cover having a second strength smaller than the first strength, and
the first portion of the optical fiber is fixed between the base and the cover.

5. The light source uniformity adjusting device of claim 1, wherein the first portion of the optical fiber is connected to a light generator.

6. The light source uniformity adjusting device of claim 1, wherein the base plate comprises a fixing area that comprises the plurality of holes, and the base plate further comprises an edge area surrounding the fixing area,
the edge area comprises a first edge and a second edge, which are opposite to each other, and
the first fixing portion is disposed at the first edge, and the second fixing portion is disposed at the second edge.

7. The light source uniformity adjusting device of claim 6, wherein a rail is along the first edge, and
the first fixing portion is movable along the rail.

8. The light source uniformity adjusting device of claim 6, further comprising a third fixing portion disposed at the first edge, and a fourth fixing portion disposed at the second edge,
wherein a second optical fiber is fixed by the third fixing portion and the fourth fixing portion.

9. The light source uniformity adjusting device of claim 1, wherein the plurality of holes are in a matrix form.

10. The light source uniformity adjusting device of claim 1, wherein the plurality of holes comprises a plurality of reference holes and at least one adjustment hole disposed to be adjacent to the plurality of reference holes.

11. The light source uniformity adjusting device of claim 1, wherein the post portion comprises:
a guide post configured to guide a shape of the optical fiber; and
a washer configured to fix the optical fiber by pushing the optical fiber in a direction of the base plate.

12. The light source uniformity adjusting device of claim 1, wherein the at least one curved shape of the optical fiber comprises:
a first curved shape having a U-type shape, disposed adjacent to the first fixing portion; and
a second curved shape having a circular shape, disposed adjacent to the second fixing portion.

13. The light source uniformity adjusting device of claim 12, wherein a shape of the second curved shape is configured to be changed to improve side shading of an image generated using light that has passed through the optical fiber.

14. The light source uniformity adjusting device of claim 12, wherein a shape of the first curved shape is configured to be changed to improve center shading of an image generated using light that has passed through the optical fiber.

15. An optical device comprising:
a light source configured to provide incident light to a substrate; and
a detector configured to detect reflective light that is generated by reflecting the incident light from the substrate, and the detector further configured to generate a spectral image,
wherein the light source comprises a light generator configured to generate the incident light, an optical fiber configured to transfer the incident light, and an adjusting device configured to coil the optical fiber, and
wherein the adjusting device comprises:
a base plate comprising a plurality of holes therein,
a first fixing portion on one side of the base plate, fixing a first portion of the optical fiber;
a second fixing portion disposed on another side of the base plate, fixing a second portion of the optical fiber; and
a post portion inserted into at least one hole from among the plurality of holes, the post portion routing the optical fiber on the base plate such that the optical fiber has at least one curved shape between the first portion and the second portion.

16. The optical device of claim 15, wherein the first fixing portion comprises a preload device, and the preload device comprises:
a fixing block fixing the first portion of the optical fiber;
an elastic body continuously providing a pushing force to the fixing block; and
an adjustment body configured to adjust a position of the fixing block.

17. The optical device of claim 15, further comprising:
a polarizer configured to rotate to a first angle to adjust a polarization direction of the incident light directed toward a measurement sample;
a compensator configured to rotate to a second angle to adjust a phase difference of the incident light;
an analyzer configured to rotate to a third angle to adjust a polarization direction of the reflective light reflected in the measurement sample; and
a controller configured to control the polarizer, the compensator, or the analyzer in accordance with at least one polarizer compensator and analyzer (PCA) angle set comprising the first angle, the second angle, and the third angle.

18. The optical device of claim 17, wherein the detector is configured to generate the spectral image from the reflective light,
wherein the optical device further comprises a processor configured to receive:
a first spectral image corresponding to a first PCA angle set, from among the at least one PCA angle set, and a first wavelength; and
a second spectral image corresponding to a second PCA angle set, from among the at least one PCA angle set, and a second wavelength different from the first wavelength and
wherein the processor is further configured to generate a polarizer compensator and analyzer rotating (PCAR) spectral matrix based on the first spectral image and the second spectral image.

19. A light source uniformity adjusting method comprising:
providing a light source uniformity adjusting device that includes: a base plate that includes a plurality of holes therein, a first fixing portion on one side of the base plate, and a second fixing portion on another side of the base plate;
fixing a second portion of an optical fiber to the second fixing portion;
inserting a post portion into at least one hole from among the plurality of holes to route the optical fiber on the base plate such that the optical fiber including at least one curved shape;
positioning a first portion of the optical fiber in the first fixing portion;
checking uniformity of an image generated, the image generated using light that has passed through the optical fiber; and
fixing the first portion of the optical fiber to the first fixing portion in accordance with a result of the checking the uniformity.

20. The light source uniformity adjusting method of claim 19, further comprising modifying a shape of the optical fiber by changing an insertion position of the post portion, with respect to the plurality of holes, based on determining that the uniformity of the image is not proper.
